(19) United States
(12) Patent Application Publication
(10) Pub. No.: US 2025/0040359 A1
(43) Pub. Date: Jan. 30, 2025

(54) DISPLAY DEVICE

(71) Applicant: Samsung Display Co., Ltd., Yongin-si (KR)

(72) Inventors: Seungbin Lee, Yongin-si (KR); Kwangsik Lee, Yongin-si (KR); Dohoon Kim, Yongin-si (KR); Cheollhee Jeon, Yongin-si (KR); Jinyong Jeong, Yongin-si (KR)

(21) Appl. No.: 18/613,953

(22) Filed: Mar. 22, 2024

(30) Foreign Application Priority Data
Jul. 27, 2023 (KR) 10-2023-0098242

(51) Int. Cl. H10K 59/124; G09G 3/3233; H10K 59/131

(52) U.S. Cl. CPC H10K 59/124; H10K 59/131; G09G 3/3233; G09G 2300/0819; G09G 2300/0842

(57) ABSTRACT

A display device includes: a substrate having a display area and a peripheral area adjacent to the display area; a first wiring in the peripheral area on the substrate; an insulating layer on the first wiring and covering at least a portion of the first wiring; a second wiring on the insulating layer, overlapping at least a portion of the insulating layer in a plan view, and having an opening pattern exposing at least a portion of the insulating layer; a first cladding part on the insulating layer and the second wiring to fill the opening pattern and exposing at least a portion of the second wiring; and a second cladding part on the second wiring and covering at least a portion of the second wiring exposed from the first cladding part.

### CROSS-REFERENCE TO RELATED APPLICATION

The present application claims priority to and the benefit of Korean Patent Application No. 10-2023-0098242, filed on Jul. 27, 2023, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

As information technology develops, the importance of display devices that provide a connection medium users and information is being highlighted. For example, the use of display devices such as liquid crystal display devices (LCDs), organic light emitting display devices (OLEDs), plasma display devices (PDPs), and quantum dot display devices is increasing.

Display devices may include an insulating layer to insulate between stacked conductive layers. Due to short-term or long-term chemical decomposition of organic matter contained in the insulating layer, the insulating layer may generate gas.

The above information disclosed in this Background section is only for enhancement of understanding of the background and therefore the information discussed in this Background section does not necessarily constitute prior art.

### SUMMARY

Aspects of some embodiments include a display device with relatively improved display quality and durability.

A display device according to some embodiments includes a substrate having a display area and a peripheral area adjacent to the display area, a first wiring in the peripheral area on the substrate, an insulating layer on the first wiring and covering at least a portion of the first wiring, a second wiring on the insulating layer, overlapping at least a portion of the insulating layer in a plan view, and having an opening pattern exposing at least a portion of the insulating layer, a first cladding part on the insulating layer and the second wiring to fill the opening pattern and exposing at least a portion of the second wiring, and a second cladding part on the second wiring and covering at least a portion of the second wiring exposed from the first cladding part.

According to some embodiments, a thickness of the second cladding part may be smaller than a thickness of the first cladding part.

According to some embodiments, a height from an upper surface of the insulating layer to an upper surface of the second cladding part may be smaller than a height from the upper surface of the insulating layer to an upper surface of the first cladding part.

According to some embodiments, the second cladding part may contact the first cladding part.

According to some embodiments, the first cladding part may be connected by the second cladding part.

According to some embodiments, the second cladding part may be spaced apart from the opening pattern in a plan view.

According to some embodiments, the first cladding part may contact the insulating layer.

According to some embodiments, the first cladding part and the second cladding part may be integrated as one body without a separate interface.

According to some embodiments, the first cladding part and the second cladding part may include an organic material.

According to some embodiments, the first wiring and the second wiring may contact each other to form a power voltage line, and the power voltage line may transmit a power voltage to a light emitting element in the display area.

A display device according to some embodiments includes a substrate having a display area and a peripheral area adjacent to the display area, a first wiring in the peripheral area on the substrate, an insulating layer on the first wiring and covering at least a portion of the first wiring, a second wiring on the insulating layer, overlapping at least a portion of the insulating layer in a plan view, and having an opening pattern exposing at least a portion of the insulating layer, a cladding film on the insulating layer and the second wiring and covering the second wiring defining the opening pattern, and at least a portion of the cladding film is located in the opening pattern, and a cladding part on the cladding film and covering at least a portion of the cladding film, and at least a portion of the cladding part is located in the opening pattern.

According to some embodiments, the cladding part may expose at least a portion of the cladding film.

According to some embodiments, a thickness of the cladding film may be smaller than a thickness of the cladding part.

According to some embodiments, a height from an upper surface of the insulating layer to an upper surface of the cladding film may be smaller than a height from the upper surface of the insulating layer to an upper surface of the cladding part.

According to some embodiments, the cladding part may contact the cladding film.

According to some embodiments, the cladding part may be in non-contact with the insulating layer by the cladding film.

According to some embodiments, he cladding film may contact the insulating layer in the opening pattern.

According to some embodiments, the cladding film may include an inorganic material, and the cladding part may include an organic material.

According to some embodiments, the first wiring and the second wiring contact each other to form a power voltage line.

According to some embodiments, the power voltage line may transmit a power voltage to a light emitting element in the display area.

In the display device according to some embodiments, a wiring having an opening pattern may be located on an insulating layer that generates gas by chemical decomposition or the like. Accordingly, the gas generated from the insulating layer may be discharged through the opening pattern.

Additionally, in the display device according to some embodiments, a first cladding part and a second cladding part may be on the wiring having the opening pattern. At this time, the first cladding part may fill the opening pattern, and the second cladding part may cover a portion of the wiring exposed in a space between openings that is not covered by the first cladding part.

Accordingly, in an area where the opening pattern is defined, the wiring may be substantially entirely covered by the first cladding part and the second cladding part. Accordingly, in the area where the opening pattern is defined, a film lifting phenomenon in which the first cladding part is lifted from the insulating layer may be reduced or prevented compared to a case where the wiring is partially covered only by the first cladding part corresponding to the opening pattern.

Additionally, in the display device according to some embodiments, the wiring having the opening pattern may be double covered by a cladding film and a cladding part. Accordingly, even if a film lifting phenomenon occurs in which the cladding part is lifted from the cladding film, the wiring may be covered by the cladding film in the area where the opening pattern is defined.

Therefore, in a display device according to some embodiments, in a subsequent process (for example, an etching process for forming a pixel electrode, etc.), penetration of an etchant into the wiring due to a lifting phenomenon may be reduced or prevented. Therefore, a problem of the wiring being damaged by reacting with the etchant may be reduced or prevented. In addition, a problem of a material included in the wiring reacting with the etchant to form particles may be reduced or prevented. Accordingly, display quality and durability of the display device may be relatively improved.

It is to be understood that both the foregoing general description and the following detailed description are illustrative and explanatory and are intended to provide further explanation of the invention as claimed, and is not intended to be limiting. As a person having ordinary skill in the art would recognize, various modifications and changes may be made to the disclosed embodiments without departing from the spirit and scope of embodiments according to the present disclosure as defined in the appended claims, and their equivalents.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to some embodiments.

FIG. 2 is a circuit diagram illustrating one of the pixels included in the display device of FIG. 1.

FIG. 3 is a cross-sectional view illustrating the display area of the display device of FIG. 1 according to some embodiments.

FIGS. 4 to 7 are layout diagrams illustrating an enlarged area A of FIG. 1 according to some embodiments.

FIG. 8 is a cross-sectional view taken along the line I-I′ of FIG. 7.

FIGS. 9 and 10 are layout diagrams illustrating an enlarged area A of FIG. 1 according to some embodiments.

FIG. 11 is a cross-sectional view taken along the line II-II′ of FIG. 10.

FIGS. 12 and 13 are layout diagrams illustrating an enlarged area A of FIG. 1 according to some embodiments.

FIG. 14 is a cross-sectional view taken along the line III-III′ of FIG. 13.

### DETAILED DESCRIPTION

Aspects of some embodiments of the present disclosure will now be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will more fully convey the scope aspects of some embodiments of the invention to those skilled in the art. Like reference numerals refer to like elements throughout.

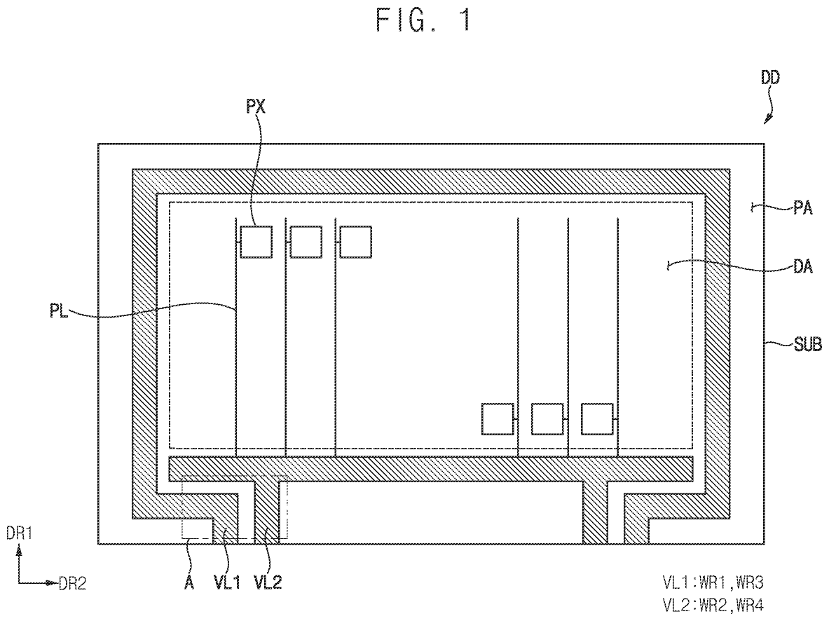

FIG. 1 is a plan view illustrating a display device according to some embodiments.

Referring to FIG. 1, a display device DD (e.g., substrate SUB) may include a display area DA and a peripheral area PA adjacent to (e.g., in a periphery or outside a footprint of) the display area DA.

The display area DA may be an area that displays images by generating light. A plurality of pixels PX that emit light may be located in the display area DA, and accordingly, the images may be displayed in the display area DA. The pixels PX may be arranged in a matrix form or arrangement (e.g., columns and rows of pixels PX) along a first direction DR1 and a second direction DR2 intersecting the first direction DR1. For example, the second direction DR2 may be perpendicular to the first direction DR1. Each of the pixels PX may include a light emitting element and a pixel circuit for driving the light emitting element. According to some embodiments, the light emitting element may include an organic light emitting diode, and the pixel circuit may include at least one thin film transistor.

Lines for providing signals or power to the pixels PX may be located in the display area DA. For example, a plurality of data signal lines, a plurality of gate signal lines, and a plurality of power lines PL may be located in the display area DA.

According to some embodiments, each of the power lines PL may extend along the first direction DR1 and may be arranged along the second direction DR2. However, embodiments according to the present invention are not necessarily limited thereto. The power lines PL may supply power voltage to the pixels PX.

The peripheral area PA may surround at least a portion of the display area DA. For example, the peripheral area PA may entirely surround the display area DA. According to some embodiments, the peripheral area PA may be an area that does not display an image. However, embodiments according to the present invention are not necessarily limited thereto, and the image may be displayed in at least a portion of the peripheral area PA.

Drivers and lines for image display may be located in the peripheral area PA. For example, a first power voltage line VL1 and a second power voltage line VL2 may be located in the peripheral area PA. The first power voltage line VL1 and the second power voltage line VL2 may provide a power voltage to at least one of the pixels PX.

For example, the first power voltage line VL1 may provide a common power voltage to the pixels PX, and the second power voltage line VL2 may provide a driving power voltage to the pixels PX. That is, the first power voltage line VL1 may be a common power voltage line, and the second power voltage line VL2 may be a driving power voltage line.

For example, the second power voltage line VL2 may provide the driving power voltage to the power line PL, and the power line PL may supply the driving power voltage to the pixels PX. Meanwhile, according to some embodiments, the driving power voltage may be higher than the common power voltage.

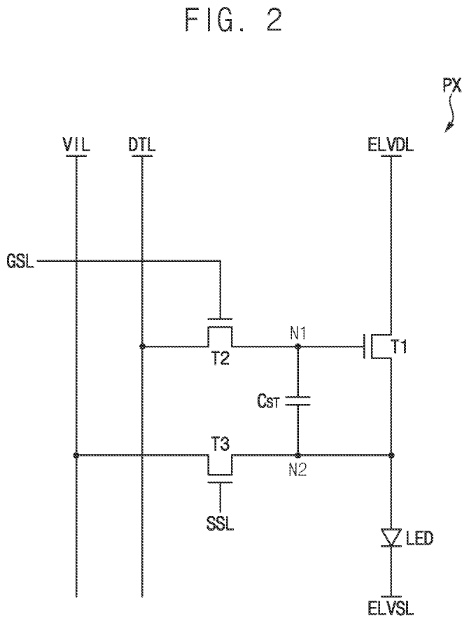

FIG. 2 is a circuit diagram illustrating one of the pixels included in the display device of FIG. 1.

Referring to FIG. 2, each of the pixels PX included in the display device DD may include a first transistor T1, a second transistor T2, a third transistor T3, a storage capacitor CST, and a light emitting element LED.

The first transistor T1 may include a source electrode, a drain electrode, and a gate electrode. The first transistor T1 may adjust a current flowing from a driving power voltage line ELVDL to which the driving power voltage is supplied to the light emitting element LED according to a voltage difference between the gate electrode and the source electrode.

For example, the first transistor T1 may be a driving transistor for driving a light emitting element LED. The gate electrode of the first transistor T1 may be connected to a first node N1. The source electrode of the first transistor T1 may be connected to a first electrode of the light emitting element LED. The drain electrode of the first transistor T1 may be connected to the driving power voltage line ELVDL to which the driving power voltage is applied.

The second transistor T2 may include a source electrode, a drain electrode, and a gate electrode. The second transistor T2 may be turned on by a gate signal of a gate signal line GSL to connect a data signal line DTL to the gate electrode of the first transistor T1. The gate electrode of the second transistor T2 may be connected to the gate signal line GSL. The source electrode of the second transistor T2 may be connected to the first node N1. The drain electrode of the second transistor T2 may be connected to the data signal line DTL.

The third transistor T3 may include a source electrode, a drain electrode, and a gate electrode. The third transistor T3 may be turned on by a sensing signal of a sensing signal line SSL to connect an initialization voltage line VIL to one end of the light emitting element LED. The gate electrode of the third transistor T3 may be connected to the sensing signal line SSL. The source electrode of the third transistor T3 may be connected to a second node N2. The drain electrode of the third transistor T3 may be connected to the initialization voltage line VIL to which an initialization voltage is applied.

However, the source electrode and the drain electrode of each of the first to third transistors T1, T2, and T3 are not limited to this, and vice versa. Additionally, each of the first to third transistors T1, T2, and T3 may be formed as a thin film transistor.

The storage capacitor CST may include a first electrode and a second electrode. The first electrode of the storage capacitor CST may be connected to the first node N1. The second electrode of the storage capacitor CST may be connected to the second node N2. The storage capacitor CST may store a difference voltage between a gate voltage and a source voltage of the first transistor T1.

The light emitting element LED may emit light according to a current supplied through the first transistor T1. The light emitting element LED may be an organic light emitting diode including a first electrode (e.g., anode electrode), an organic light emitting layer, and a second electrode (e.g., cathode electrode). However, embodiments of the present invention are not limited thereto, and the light emitting element LED may be an inorganic light emitting diode including an inorganic light emitting layer, a quantum dot light emitting diode including a quantum dot light emitting layer, or the like. Additionally, the light emitting element LED may be a micro-LED. The first electrode of the light emitting element LED may be connected to the source electrode of the first transistor T1, and the second electrode of the light emitting element LED may be connected to a common power voltage line ELVSL to which the common power voltage lower than the driving power voltage is applied.

Meanwhile, in FIG. 2, a case where each of the pixels PX includes three transistors, one storage capacitor, and one light emitting element has been described. However, the number of transistors, the number of storage capacitors, and the number of light emitting elements included in each of the pixels PX are not limited thereto. For example, according to some embodiments, the pixels PX may include additional components or fewer components without departing from the spirit and scope of embodiments according to the present disclosure.

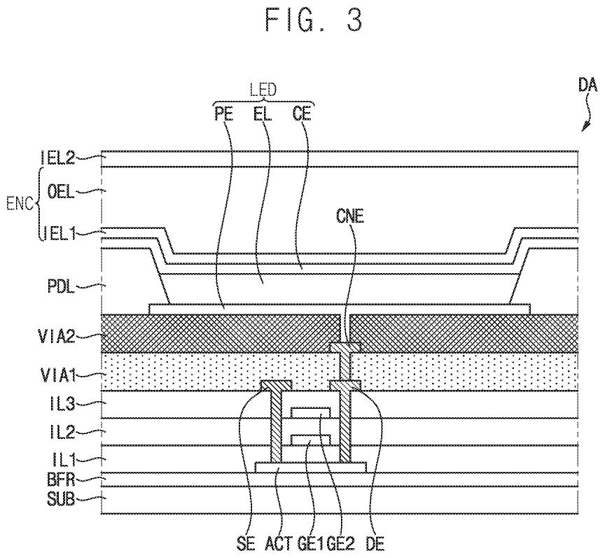

FIG. 3 is a cross-sectional view illustrating the display area of the display device of FIG. 1 according to some embodiments.

Referring to FIGS. 1 and 3, the display device DD may include a substrate SUB, a buffer layer BFR, an active pattern ACT, a first gate electrode GE1, a second gate electrode GE2, a source electrode SE, a drain electrode DE, a connection electrode CNE, a first interlayer insulating layer IL1, a second interlayer insulating layer IL2, a third interlayer insulating layer IL3, a first via insulating layer VIA1, a second via insulating layer VIA2, a pixel defining layer PDL, a pixel electrode PE, a light emitting layer EL, a common electrode CE, and an encapsulation layer ENC.

The substrate SUB may include a transparent or opaque material. According to some embodiments, examples of materials that can be used as a substrate SUB may include glass, quartz, plastic, or the like. These can be used alone or in combination with each other.

The buffer layer BFR may be located on the substrate SUB. The buffer layer BFR may prevent or produce instances of metal atoms or impurities diffusing from the substrate SUB to the active pattern ACT. According to some embodiments, the buffer layer BFR may be formed of an insulating material. Examples of insulating materials that can be used as the buffer layer BFR may include silicon oxide, silicon nitride, and silicon oxynitride.

The active pattern ACT may be located on the buffer layer BFR. According to some embodiments, the active pattern ACT may be formed of a silicon semiconductor material, an oxide semiconductor material, or an organic semiconductor material.

The first interlayer insulating layer IL1 may be located on the active pattern ACT. The first interlayer insulating layer IL1 may cover the active pattern ACT. According to some embodiments, the first interlayer insulating layer IL1 may be formed of an insulating material. Examples of insulating materials that can be used as the first interlayer insulating layer IL1 may include silicon oxide, silicon nitride, and silicon oxynitride. These can be used alone or in combination with each other.

The first gate electrode GE1 may be located on the first interlayer insulating layer IL1. The first gate electrode GE1 may overlap the active pattern ACT. According to some embodiments, the first gate electrode GE1 may be formed of metal, alloy, conductive metal oxide, transparent conductive material, or the like.

The second interlayer insulating layer IL2 may be located on the first gate electrode GE1. The second interlayer insulating layer IL2 may cover the second gate electrode GE2. According to some embodiments, the second interlayer insulating layer ILD2 may be formed of an insulating material. Examples of insulating materials that can be used as the second interlayer insulating layer IL2 may include silicon oxide, silicon nitride, and silicon oxynitride. These can be used alone or in combination with each other.

The second gate electrode GE2 may be located on the second interlayer insulating layer IL2. The second gate electrode GE2 may overlap the first gate electrode GE1. According to some embodiments, the second gate electrode GE2 may be formed of metal, alloy, conductive metal oxide, transparent conductive material, or the like.

The third interlayer insulating layer IL3 may be located on the second gate electrode GE2. The third interlayer insulating layer IL3 may cover the second gate electrode GE2. According to some embodiments, the third interlayer insulating layer ILD3 may be formed of an insulating material. Examples of insulating materials that can be used as the third interlayer insulating layer IL3 may include silicon oxide, silicon nitride, and silicon oxynitride. These can be used alone or in combination with each other.

The source electrode SE and the drain electrode DE may be located on the third interlayer insulating layer IL3. The source electrode SE and drain electrode DE may contact the active pattern ACT. According to some embodiments, the source electrode SE and the drain electrode DE may be formed of metal, alloy, conductive metal oxide, transparent conductive material, or the like.

The active pattern ACT, the first gate electrode GE1, the source electrode SE, and the drain electrode DE may form a transistor. For example, the active pattern ACT, the first gate electrode GE1, the source electrode SE, and the drain electrode DE may form the first transistor T1 of FIG. 2. The first gate electrode GE1 and the second gate electrode GE2 may form a capacitor. For example, the first gate electrode GE1 and the second gate electrode GE2 may form the storage capacitor CST of FIG. 2.

The first via insulating layer VIA1 may be located on the source electrode SE and the drain electrode DE. The first via insulating layer VIA1 may cover the source electrode SE and the drain electrode DE. The first via insulating layer VIA1 may be formed of an organic insulating material. Examples of organic insulating materials that can be used as the first via insulating layer VIA1 may include photoresist, polyacrylic resin, polyimide resin, polyamide resin, acrylic resin, and epoxy resin. These can be used alone or in combination with each other.

The connection electrode CNE may be located on the first via insulating layer VIA1. The connection electrode CNE may contact at least one of the source electrode SE or the drain electrode DE. For example, the connection electrode CNE may contact the drain electrode DE. The connection electrode CNE may connect the pixel electrode PE and the transistor. The connection electrode CNE may be formed of metal, alloy, conductive metal oxide, transparent conductive material, or the like.

The second via insulating layer VIA2 may be located on the connection electrode CNE. The second via insulating layer VIA2 may cover the connection electrode CNE. The second via insulating layer VIA2 may be formed of an organic insulating material. Examples of organic insulating materials that can be used as the second via insulating layer VIA2 may include photoresist, polyacrylic resin, polyimide resin, polyamide resin, acrylic resin, and epoxy resin. These can be used alone or in combination with each other.

The pixel electrode PE may be located on the second via insulating layer VIA2. The pixel electrode PE may function as an anode electrode or a cathode electrode. For example, the pixel electrode PE may function as an anode electrode. The pixel electrode PE may include a conductive material such as a metal, alloy, conductive metal nitride, conductive metal oxide, or transparent conductive material. The pixel electrode PE may have a single-layer structure or a multi-layer structure including a plurality of conductive layers.

The pixel defining layer PDL may be located on the second via insulating layer VIA2 and the pixel electrode PE. The pixel defining layer PDL may be formed of an insulating material. Examples of insulating materials that can be used as the pixel defining layer PDL may include photoresist, polyacrylic resin, polyimide resin, polyamide resin, siloxane resin, acrylic resin, and epoxy resin. These can be used alone or in combination with each other. The pixel defining layer PDL may define a pixel opening that exposes at least a portion of the pixel electrode PE.

The light emitting layer EL may be located on the pixel electrode PE exposed by the pixel opening of the pixel defining layer PDL. According to some embodiments, the light emitting layer EL may have a multi-layer structure including a hole injection layer, a hole transport layer, an electron transport layer, and an electron injection layer.

The common electrode CE may be located on the pixel defining layer PDL and the light emitting layer EL. The common electrode CE may function as a cathode electrode or an anode electrode. For example, the common electrode CE may function as a cathode electrode. The common electrode CE may include a conductive material such as a metal, alloy, conductive metal nitride, conductive metal oxide, or transparent conductive material. The common electrode CE may have a single-layer structure or a multi-layer structure including a plurality of conductive layers. The pixel electrode PE, the light emitting layer EL, and the common electrode CE may form the light emitting element LED.

The encapsulation layer ENC may be located on the light emitting element LED. The encapsulation layer ENC may prevent or reduce instances of impurities or contaminants penetrating into the light emitting element LED. The encapsulation layer ENC may include at least one inorganic encapsulation layer and at least one organic encapsulation layer. According to some embodiments, the encapsulation layer ENC may include a first inorganic encapsulation layer IEL1, an organic encapsulation layer OEL, and a second inorganic encapsulation layer IEL2. The first inorganic encapsulation layer IEL1 may be located on the common electrode CE. The organic encapsulation layer OEL may be located on the first inorganic encapsulation layer IEL1. The second inorganic encapsulation layer IEL2 may be located on the organic encapsulation layer OEL.

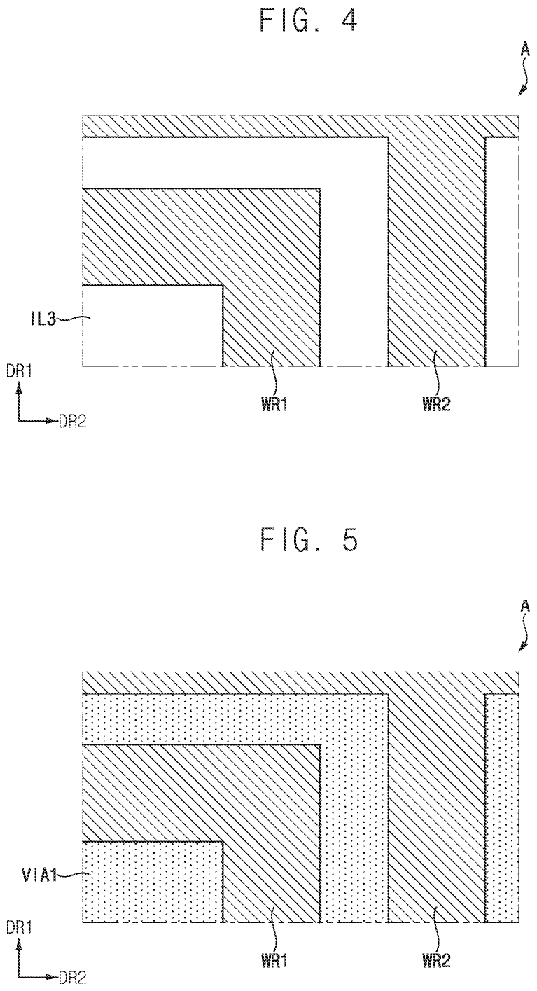

FIGS. 4 to 7 are layout diagrams illustrating an enlarged area A of FIG. 1 according to some embodiments. For example, FIGS. 4 to 7 may be enlarged layout diagrams of the first and second power voltage lines VL1 and VL2 in the peripheral area PA.

First, referring to FIGS. 1, 3, and 4, the first interlayer insulating layer IL1, the second interlayer insulating layer IL2, and the third interlayer insulating layer IL3 may be sequentially arranged on the substrate SUB. Additionally, the first wiring WR1 and the second wiring WR2 may be located on the third interlayer insulating layer IL3. Descriptions of the substrate SUB, the first interlayer insulating layer IL1, the second interlayer insulating layer IL2, and the third interlayer insulating layer IL3 are omitted since they overlap with the description with reference to FIG. 3.

The first wiring WR1 and the second wiring WR2 may extend in the first direction DR1 and/or the second direction DR2. The first wiring WR1 and the second wiring WR2 may include a conductive material. Examples of conductive materials that can be used as the first wiring WR1 and the second wiring WR2 may include aluminum, platinum, palladium, silver, magnesium, gold, nickel, neodymium, iridium, chromium, lithium, calcium, and molybdenum, titanium, tungsten, copper, or the like. These can be used alone or in combination with each other. According to some embodiments, the first wiring WR1 and the second wiring WR2 may be formed in the same process as the source electrode SE and the drain electrode DE. That is, the first wiring WR1 and the second wiring WR2 may include the same material as the source electrode SE and the drain electrode DE.

Referring further to FIG. 5, the first via insulating layer VIA1 may be located on the first wiring WR1 and the second wiring WR2. According to some embodiments, the first via insulating layer VIA1 may cover at least a portion of the first wiring WR1 and at least a portion of the second wiring WR2. Additionally, the first via insulating layer VIA1 may expose at least a portion of the first and second wiring WR1 and at least a portion of the second wiring WR2. The first via insulating layer VIA1 may contact at least a portion of the third interlayer insulating layer IL3. As described above, the first via insulating layer VIA1 may include an organic insulating material.

Referring further to FIG. 6, the third and fourth wirings WR3 and WR4 may be located on the first via insulating layer VIA1.

The third wiring WR3 and the fourth wiring WR4 may overlap at least a portion of the first via insulating layer VIA1 in a plan view. The third wiring WR3 and the fourth wiring WR4 may have an opening pattern OPP exposing at least a portion of the first via insulating layer VIA1 in an area overlapping the first via insulation layer VIA1. That is, the opening pattern OPP of each of the third wiring WR3 and the fourth wiring WR4 may expose at least a portion of the first via insulating layer VIA1. For example, the opening pattern OPP may be defined by a plurality of openings repeatedly arranged along the first direction DR1 and the second direction DR2.

Since the first via insulating layer VIA1 includes an organic insulating material, gas may be generated from the first via insulating layer VIA1 due to short-term or long-term chemical decomposition. If the gas is not properly discharged, the light emitting element LED located in the display area DA may be damaged by the gas, causing pixel shrinkage and reduced lifespan of the light emitting element LED.

According to embodiments, since each of the third wiring WR3 and the fourth wiring WR4 located on the first via insulating layer VIA1 includes the opening pattern OPP, the gas generated from the first via insulating layer VIA1 may be discharged through the opening pattern OPP.

The third wiring WR3 and the fourth wiring WR4 may include a conductive material. Examples of conductive materials that can be used as the third wiring WR3 and the fourth wiring WR4 may include aluminum, platinum, palladium, silver, magnesium, gold, nickel, neodymium, iridium, chromium, lithium, calcium, and molybdenum, titanium, tungsten, copper, or the like. These can be used alone or in combination with each other. According to some embodiments, the third wiring WR3 and the fourth wiring WR4 may be formed in the same process as the connection electrode CNE. That is, the third wiring WR3 and the fourth wiring WR4 may include the same material as the connection electrode CNE.

Meanwhile, the third wiring WR3 may overlap at least a portion of the first wiring WR1, and the fourth wiring WR4 may overlap at least a portion of the second wiring WR2. For example, the third wiring WR3 may be in contact with the first wiring WR1 exposed from the first via insulating layer VIA1, and the fourth wiring WR4 may be in contact with the second wiring WR2 exposed from first via insulating layer VIA1.

The first wiring WR1 and the third wiring WR3 may contact each other to form the first power voltage wiring VL1, and the second wiring WR2 and the fourth wiring WR4 may contact each other to form the second power voltage wiring VL2.

Referring further to FIG. 7, a first cladding part CDP1 and a second cladding part CDP2 may be located on the first via insulating layer VIA1, the third wiring WR3, and the fourth wiring WR4.

The first cladding part CDP1 may fill the opening pattern OPP of each of the third wiring WR3 and the fourth wiring WR4. That is, the first cladding part CDP1 may be arranged to correspond to the opening pattern OPP. Accordingly, the first cladding part CDP1 may contact the first via insulating layer VIA1 at the opening pattern OPP. According to some embodiments, the first cladding part CDP1 may cover a portion of each of the third wiring WR3 and the fourth wiring WR4.

The first cladding part CDP1 may include an organic insulating material. Examples of organic insulating materials that can be used as the first cladding portion CDP1 may include photoresist, polyacrylic resin, polyimide resin, polyamide resin, acrylic resin, and epoxy resin. These can be used alone or in combination with each other.

According to some embodiments, the first cladding part CDP1 may be formed in the same process as the second via insulating layer VIA2. That is, the first cladding part CDP1 may include the same material as the second via insulating layer VIA2. For example, the first cladding part CDP1 and the second via insulation layer VIA2 may be formed simultaneously by applying a preliminary layer containing an organic insulating material on the first via insulating layer VIA1, the third wiring WR3, the fourth wiring WR4, and the connection electrode CNE and exposing and developing the preliminary layer.

The second cladding part CDP2 may cover at least a portion of each of third wiring WR3 and the fourth wiring WR4 exposed from the first cladding part CDP1. For example, the second cladding part CDP2 may be spaced apart from the opening pattern OPP in a plan view. That is, the second cladding part CDP2 may be located in a space between the openings defining the opening pattern OPP. In other words, the second cladding part CDP2 may cover a portion of each of the third wiring WR3 and the fourth wiring WR4 exposed in the space between the openings defining the opening pattern OPP. Specifically, the second cladding part CDP2 may cover a portion of the third wiring WR3 and the fourth wiring WR4 exposed in the space that are not covered by the first cladding part CDP1.

According to some embodiments, the second cladding part CDP2 may be in contact with the first cladding part CDP1. For example, the second cladding part CDP2 may contact a side surface of the first cladding part CDP1. Accordingly, the first cladding part CDP1 may be connected by the second cladding part CDP2. In other words, the first cladding part CDP1 arranged to correspond to the opening pattern OPP may be connected by the second cladding part CDP2.

The second cladding part CDP2 may include an organic insulating material. Examples of organic insulating materials that can be used as the second cladding part CDP2 may include photoresist, polyacrylic resin, polyimide resin, polyamide resin, acrylic resin, and epoxy resin. These can be used alone or in combination with each other.

According to some embodiments, the second cladding part CDP2 may be formed in the same process as the first cladding part CDP1. That is, the second cladding part CDP2 may include the same material as the first cladding part CDP1. For example, the first cladding part CDP1 and the second cladding part CDP2 may be integrated as one body without a separate interface. For example, the first cladding part CDP1 and the second cladding part CDP2 may be formed simultaneously by applying a preliminary layer containing an organic insulating material on the first via insulating layer VIA1, the third wiring WR3, and the fourth wiring WR4 and exposing and developing the preliminary layer.

According to some embodiments, the first cladding part CDP1, the second cladding part CDP2, and the second via insulating layer VIA2 may be formed together in the same process. That is, the first cladding part CDP1, the second cladding part CDP2, and the second via insulating layer VIA2 may include the same material. In this case as well, the first cladding part CDP1 and the second cladding part CDP2 may be integrated as one body without a separate interface. For example, the first cladding part CDP1, the second cladding part CDP2, and the second via insulating layer VIA2 may be formed simultaneously by applying a preliminary layer containing an organic insulating material on the first via insulating layer VIA1, the third wiring WR3, and the fourth wiring WR4 and exposing and developing the preliminary layer.

In the display device DD according to embodiments, the second cladding part CDP2 may be located on the third wiring WR3 and the fourth wiring WR4 having the opening pattern OPP. In addition, the second cladding part CDP2 may cover a portion of the third wiring WR3 and the fourth wiring WR4 exposed in the space between the openings that is not covered by the first cladding part CDP1. Accordingly, in an area where the opening pattern OPP is defined, the third wiring WR3 and the fourth wiring WR4 may be substantially entirely covered by the first cladding part CDP1 and the second cladding part CDP2.

Accordingly, in the area where the opening pattern OPP is defined, a film lifting phenomenon in which the first cladding part CDP1 is lifted from the first via insulating layer VIA1 may be reduced or prevented compared to a case where the third wiring WR3 and the fourth wiring WR4 are partially covered only by the first cladding part CDP1 located corresponding to the opening pattern OPP.

Accordingly, in a subsequent process (for example, an etching process for forming the pixel electrode PE, etc.), penetration of an etchant into the third wiring WR3 and/or the fourth wiring WR4 due to a lifting phenomenon of the first cladding part CDP1 may be reduced or prevented. Therefore, a problem of the third wiring WR3 and/or the fourth wiring WR4 are damaged by reacting with the etchant may be reduced or prevented. In addition, a problem of a material included in the third wiring WR3 and/or the fourth wiring WR4 reacting with the etchant to form particles may be reduced or prevented. Accordingly, display quality and durability of the display device DD may be improved.

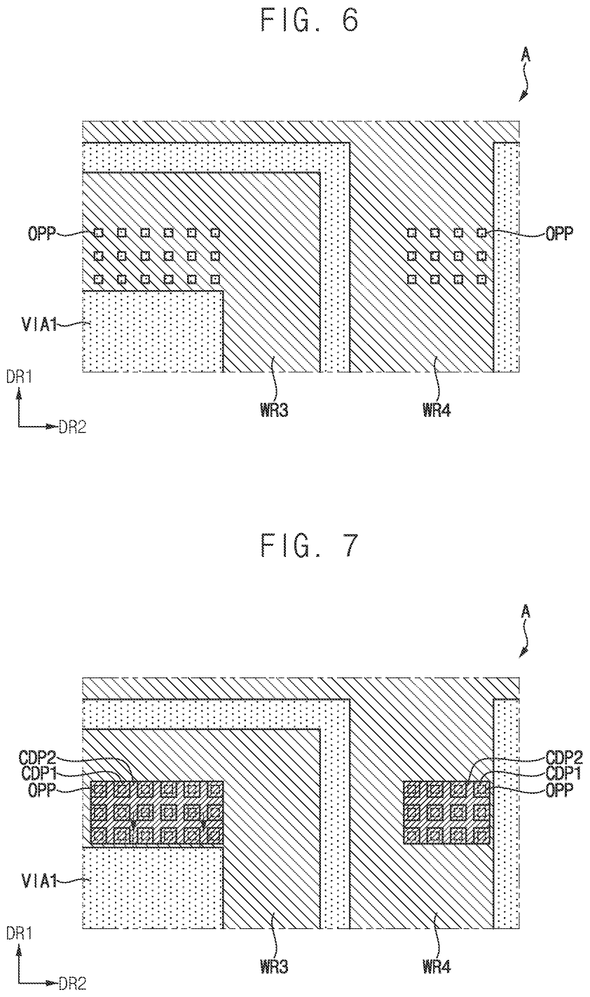

FIG. 8 is a cross-sectional view taken along line I-I′ of FIG. 7.

In FIG. 8, for convenience of description, only a cross-sectional structure of an area where the opening pattern OPP defined in the third wiring WR3 and the first and second cladding parts CDP1 and CDP2 corresponding to the third wiring WR3 are located is illustrated. A cross-sectional structure of an area where the opening pattern OPP defined in the fourth wiring WR4 and the first and second cladding parts CDP1 and CDP2 corresponding to the fourth wiring WR4 are located may be substantially same as the cross-sectional structure of FIG. 8.

Referring further to FIG. 8, according to some embodiments, a thickness of the second cladding part CDP2 may be different from a thickness of the first cladding part CDP1. That is, an upper surface of the first cladding part CDP1 and an upper surface of the second cladding part CDP2 may be located at different levels. Specifically, the thickness of the second cladding part CDP2 may be smaller than the thickness of the first cladding part CDP1. That is, the upper surface of the second cladding part CDP2 may be located at a lower level than the upper surface of the first cladding part CDP1. For example, a height from an upper surface of the first via insulating layer VIA1 to the upper surface of the second cladding part CDP2 may be smaller than a height from the upper surface of the first via insulating layer VIA1 to the upper surface of the first cladding part CDP1.

For example, when the first cladding part CDP1 and the second cladding part CDP2 are integrated as one body, the first cladding part CDP1 and the second cladding part CDP2 having different thicknesses from each other may be formed simultaneously by applying a preliminary layer containing an organic insulating material on the first via insulating layer VIA1, the third wiring WR3, and the fourth wiring WR4 and exposing and developing the preliminary layer by a halftone mask, etc.

For example, a full-tone area of the halftone mask may correspond to a portion corresponding to the first cladding part CDP1 of the preliminary layer, and the half-tone area of the halftone mask may correspond to a portion corresponding to the second cladding part CDP2 of the preliminary layer. Accordingly, an amount of light irradiated to the portion corresponding to the second cladding part CDP2 of the preliminary layer may be less than an amount of light irradiated to the portion corresponding to the first cladding part CDP1 of the preliminary layer. depending on a difference in the amount of light irradiation, in the subsequent development process, the portion of the preliminary layer corresponding to the full-tone area may remain as the first cladding part CDP1, and the portion of the preliminary layer corresponding to the half-tone area may remain as the second cladding part CDP2 with a thickness smaller than a thickness of the first cladding part CDP1.

Meanwhile, in another example, depending on a type of photosensitive material included in the preliminary layer, the amount of light irradiated to the portion corresponding to the second cladding part CDP2 of the preliminary layer may be more than the amount of light irradiated to the portion corresponding to the first cladding part CDP1 of the preliminary layer.

As the second cladding part CDP2 has a smaller thickness than the first cladding part CDP1, a path (e.g., space where the first cladding part CDP1 is not located on the third wiring WR3 and the fourth wiring WR4) of the gas generated from the first via insulating layer VIA1 and discharged through the opening pattern OPP may not be blocked. That is, even when the second cladding part CDP2 is located on the third wiring WR3 and the fourth wiring WR4, the discharging of the gas through the opening pattern OPP may not be reduced or suppressed.

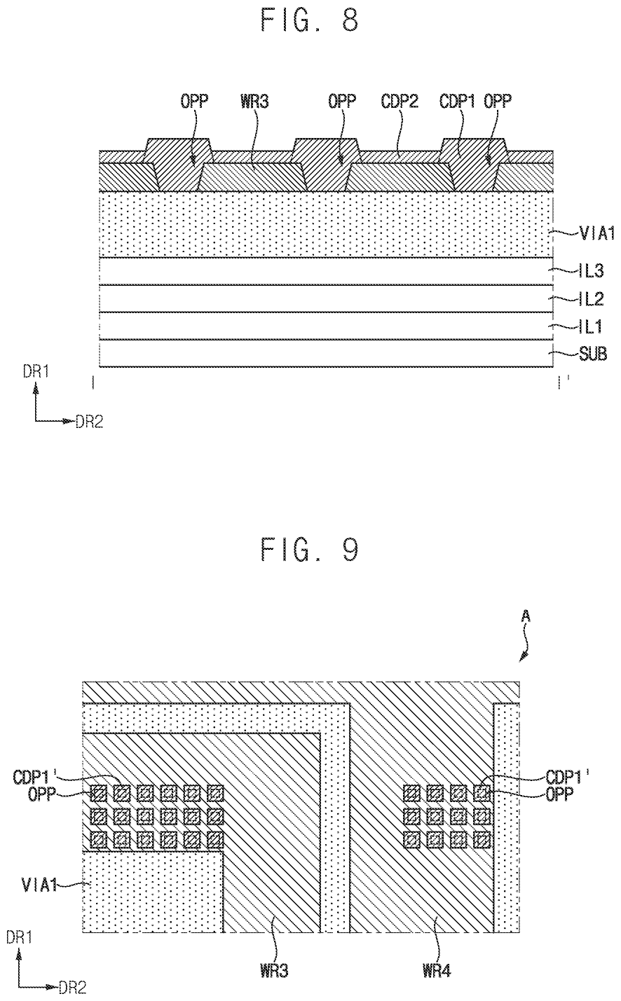

FIGS. 9 and 10 are layout diagrams illustrating an enlarged area A of FIG. 1 according to some embodiments.

For example, embodiments described with reference to FIGS. 9 and 10 may be substantially same as embodiments describe with reference to FIGS. 4 to 7 except for including a first cladding part CDP1′ and a second cladding part CDP2′ instead of the first cladding part CDP and the second cladding part CDP2. In addition, the first and second cladding parts CDP1, CDP2′ are substantially same as the first and second cladding parts CDP1, CDP2 described with reference to FIG. 7 except that the first and second cladding parts CDP1, CDP2′ are separate structures that are not formed integrally with each other. Therefore, overlapping descriptions are omitted or simplified.

As described with reference to FIG. 6, the third wiring WR3 and the fourth wiring WR4 may have the opening pattern OPP that exposes at least a portion of the first via insulating layer VIA1.

Referring further to FIGS. 9 and 10, the first cladding part CDP1′ and a second cladding part CDP2′ may be located on the first via insulating layer VIA1, the third wiring WR3, and the fourth wiring WR4.

For example, as illustrated in FIG. 9, the first cladding part CDP1′ may be arranged to fill the opening pattern OPP of each of the third wiring WR3 and the fourth wiring WR4. That is, the first cladding part CDP1′ may be arranged to correspond to the opening pattern OPP. Accordingly, the first cladding part CDP1′ may contact the first via insulating layer VIA1 at the opening pattern OPP.

The first cladding part CDP1′ may include an organic insulating material. Examples of organic insulating materials that can be used as the first cladding part CDP1′ may include photoresist, polyacrylic resin, polyimide resin, polyamide resin, acrylic resin, and epoxy resin. These can be used alone or in combination with each other.

According to some embodiments, the first cladding part CDP1′ may be formed in the same process as the second via insulating layer VIA2. That is, the first cladding part CDP1′ may include the same material as the second via insulating layer VIA2. For example, the first cladding part CDP1′ and the second via insulating layer VIA2 may be formed simultaneously by applying a preliminary layer containing an organic insulating material on the first via insulating layer VIA1, the third wiring WR3, the fourth wiring WR4, and the connection electrode CNE and exposing and developing the preliminary layer.

As illustrated in FIG. 10, the second cladding part CDP2′ may cover at least a portion of each of third wiring WR3 and the fourth wiring WR4 exposed from the first cladding part CDP1′. For example, the second cladding part CDP2′ may be arranged to be spaced apart from the opening pattern OPP in a plan view. That is, the second cladding part CDP2′ may be located in a space between the openings defining the opening pattern OPP. In other words, the second cladding part CDP2′ may cover a portion of each of the third wiring WR3 and the fourth wiring WR4 exposed in the space between the openings defining the opening pattern OPP. Specifically, the second cladding part CDP2′ may cover a portion of the third wiring WR3 and the fourth wiring WR4 exposed in the space that are not covered by the first cladding part CDP1″.

According to some embodiments, the second cladding part CDP2′ may be in contact with the first cladding part CDP1′. For example, the second cladding part CDP2′ may contact a side surface of the first cladding part CDP1. Accordingly, the first cladding part CDP1′ may be connected by the second cladding part CDP2′. In other words, the first cladding part CDP1′ arranged to correspond to the opening pattern OPP may be connected by the second cladding part CDP2′.

According to some embodiments, the second cladding part CDP2′ may be formed in a separate process from the first cladding part CDP1. For example, the second cladding part CDP2′ may be formed after forming the first cladding part CDP1. For example, the second cladding part CDP2′ may be formed by applying a preliminary layer containing an organic insulating material on the third wiring WR3, the fourth wiring WR4, and the first cladding part CDP1′ and exposing and developing the preliminary layer.

According to some embodiments, the second cladding part CDP2′ may include an organic insulating material. Examples of organic insulating materials that can be used as the second cladding part CDP2′ may include photoresist, polyacrylic resin, polyimide resin, polyamide resin, acrylic resin, and epoxy resin. These can be used alone or in combination with each other.

According to some embodiments, the second cladding part CDP2′ may include an inorganic insulating material. Examples of inorganic insulating materials that can be used as the second cladding part CDP2 may include silicon oxide, silicon nitride, and silicon oxynitride. These can be used alone or in combination with each other.

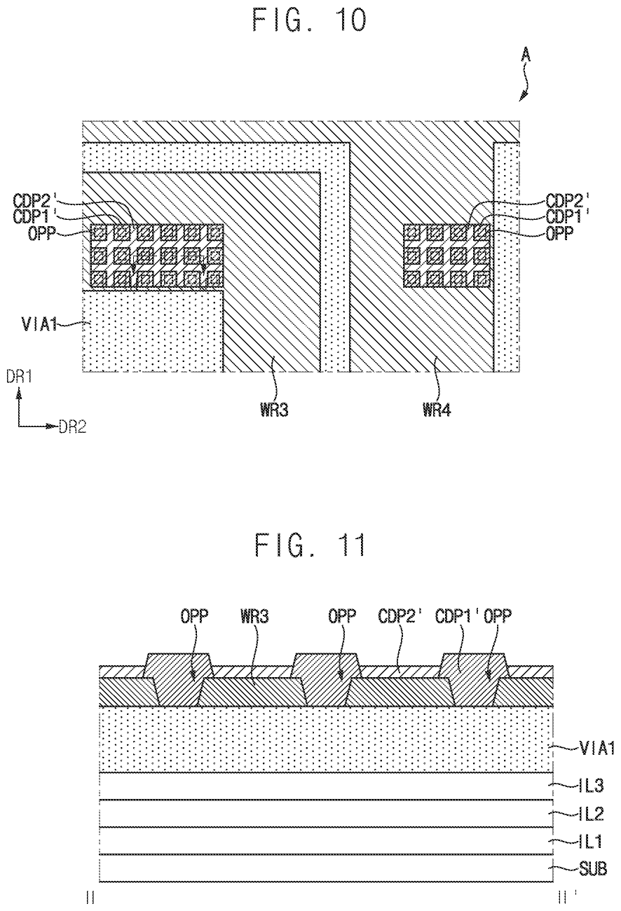

FIG. 11 is a cross-sectional view taken along line II-II′ of FIG. 10.

In FIG. 11, for convenience of description, only a cross-sectional structure of an area where the opening pattern OPP defined in the third wiring WR3 and the first and second cladding parts CDP1′ and CDP2′ corresponding to the third wiring WR3 are located is illustrated. A cross-sectional structure of an area where the opening pattern OPP defined in the fourth wiring WR4 and the first and second cladding parts CDP1′ and CDP2′ corresponding to the fourth wiring WR4 are located may be substantially same as the cross-sectional structure of FIG. 11.

Referring further to FIG. 11, according to some embodiments, a thickness of the second cladding part CDP2′ may be different from a thickness of the first cladding part CDP1′. That is, an upper surface of the first cladding part CDP1′ and an upper surface of the second cladding part CDP2′ may be located at different levels. Specifically, the thickness of the second cladding part CDP2′ may be smaller than the thickness of the first cladding part CDP1. That is, the upper surface of the second cladding part CDP2′ may be located at a lower level than the upper surface of the first cladding part CDP1′. For example, a height from an upper surface of the first via insulating layer VIA1 to the upper surface of the second cladding part CDP2′ may be smaller than a height from the upper surface of the first via insulating layer VIA1 to the upper surface of the first cladding part CDP1.

That is, even in the case where the first cladding part CDP1′ and the second cladding part CDP2′ are not formed integrally and are of separate configuration, the thickness of the second cladding part CDP2′ may be smaller than the thickness of the first cladding part CDP1.

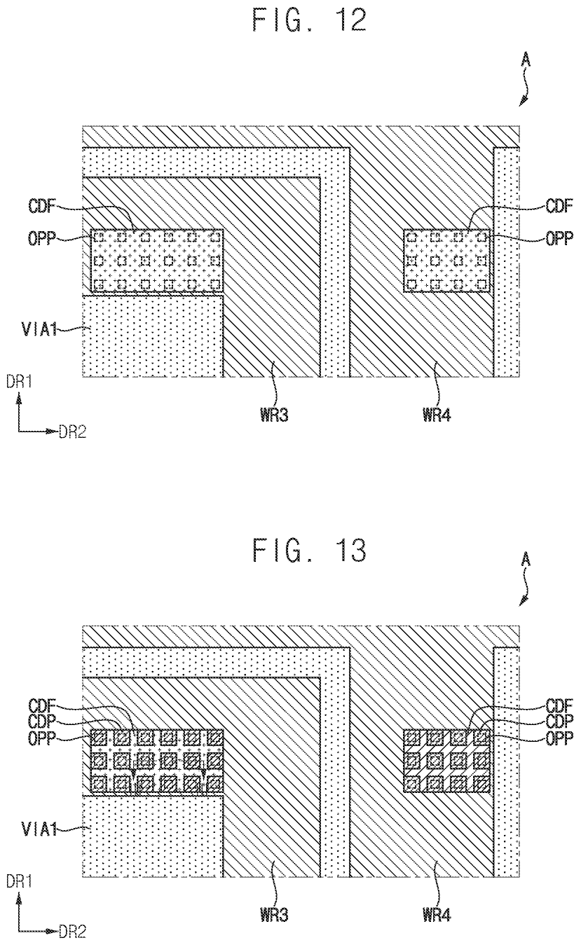

FIGS. 12 and 13 are layout diagrams illustrating an enlarged area A of FIG. 1 according to some embodiments.

For example, embodiments described with reference to FIGS. 12 and 13 may be substantially same as embodiments describe with reference to FIGS. 4 to 7 except for including a cladding film CDF and a cladding part CDP instead of the first cladding part CDP and the second cladding part CDP2. Therefore, overlapping descriptions are omitted or simplified.

As described with reference to FIG. 6, the third wiring WR3 and the fourth wiring WR4 may have the opening pattern OPP that exposes at least a portion of the first via insulating layer VIA1.

Referring further to FIGS. 12 and 13, the cladding film CDF and the cladding part CDP may be located on the first via insulating layer VIA1, the third wiring WR3, and the fourth wiring WR4.

As illustrated in FIG. 12, at least a portion of the cladding film CDF may be located in the opening pattern OPP of each of third wiring WR3 and the fourth wiring WR4. Accordingly, the cladding film CDF may contact the first via insulating layer VIA1 at the opening pattern OPP. Meanwhile, in an area where the opening pattern OPP is defined, the third wiring WR3 and the fourth wiring WR4 may be substantially entirely covered by the cladding film CDF.

The cladding film CDF may include an inorganic insulating material. Examples of inorganic insulating materials that can be used as the cladding film CDF may include silicon oxide, silicon nitride, and silicon oxynitride. These can be used alone or in combination with each other.

As illustrated in FIG. 13, the cladding part CDP may be located on the cladding film CDF. For example, the cladding part CDP may contact the cladding film CDF. Specifically, the cladding part CDP may cover at least a portion of the cladding film CDF. For example, the cladding part CDP may cover a portion of the cladding film CDF and expose another portion of the cladding film CDF.

At least a portion of the cladding part CDP may be located in the opening pattern OPP. For example, the cladding part CDP may be arranged to fill an excess space of the opening pattern OPP that is not filled by the cladding film CDF. That is, the cladding part CDP may be arranged to correspond to the opening pattern OPP. Accordingly, the cladding part CDP may contact the cladding film CDF in the opening pattern OPP.

The cladding part CDP may include an organic insulating material. Examples of organic insulating materials that can be used as the cladding part CDP may include photoresist, polyacrylic resin, polyimide resin, polyamide resin, acrylic resin, and epoxy resin. These can be used alone or in combination with each other.

According to some embodiments, the cladding part CDP may be formed in the same process as the second via insulating layer VIA2. That is, the cladding part CDP may include the same material as the second via insulating layer VIA2. For example, the cladding part CDP and the second via insulating layer VIA2 may be formed simultaneously by applying a preliminary layer containing an organic insulating material on the first via insulating layer VIA1, the third wiring WR3, the fourth wiring WR4, and the connection electrode CNE and exposing and developing the preliminary layer.

According to some embodiments, the cladding part CDP may not contact the first via insulating layer VIA1. That is, as the cladding film CDF is located on the first via insulating layer VIA1 in the opening pattern OPP and the cladding part CDP is formed on the cladding film CDF, the cladding part CDP may not contact the first via insulating layer VIA1.

In an area where the opening pattern OPP is defined, the third wiring WR3 and the fourth wiring WR4 may be double covered by the cladding film CDF and the cladding part CDP. Accordingly, even if a film lifting phenomenon occurs in which the cladding part CDP is lifted from the cladding film CDF, the third wiring WR3 and the fourth wiring WR4 may be covered by the cladding film CDF in the area where the opening pattern OPP is defined.

Accordingly, in a subsequent process (for example, an etching process for forming the pixel electrode PE, etc.), penetration of an etchant into the third wiring WR3 and/or the fourth wiring WR4 due to a lifting phenomenon of the cladding part CDP may be reduced or prevented. Therefore, a problem of the third wiring WR3 and/or the fourth wiring WR4 are damaged by reacting with the etchant may be reduced or prevented. In addition, a problem of a material included in the third wiring WR3 and/or the fourth wiring WR4 reacting with the etchant to form particles may be reduced or prevented. Accordingly, display quality and durability of the display device DD may be improved.

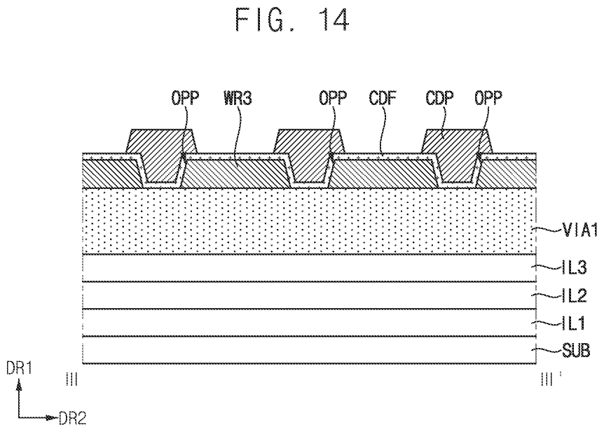

FIG. 14 is a cross-sectional view taken along line III-III′ of FIG. 13.

In FIG. 14, for convenience of description, only a cross-sectional structure of an area where the opening pattern OPP defined in the third wiring WR3 and the cladding film CDF and cladding part CDP corresponding to the third wiring WR3 are located is illustrated. A cross-sectional structure of an area where the opening pattern OPP defined in the third wiring WR3 and the cladding film CDF and cladding part CDP corresponding to the fourth wiring WR4 are located may be substantially same as the cross-sectional structure of FIG. 14.

Referring further to FIG. 14, according to some embodiments, a thickness of the cladding film CDF may be different from a thickness of the cladding part CDP. That is, an upper surface of the cladding film CDF and an upper surface of the cladding part CDP may be located at different levels. Specifically, the thickness of the cladding film CDF may be smaller than the thickness of the cladding part CDP. That is, the upper surface of the cladding film CDF may be located at a lower level than the upper surface of the cladding part CDP. For example, a height from an upper surface of the first via insulating layer VIA1 to the upper surface of the cladding film CDF may be smaller than a height from the upper surface of the first via insulating layer VIA1 to the upper surface of the cladding part CDP.

As the cladding film CDF has a smaller thickness than the cladding part CDP, a path (e.g., space where the cladding part CDP is not located on the third wiring WR3 and the fourth wiring WR4) of the gas generated from the first via insulating layer VIA1 and discharged through the opening pattern OPP may not be blocked. That is, even when the cladding film CDF is located on the third wiring WR3 and the fourth wiring WR4, the discharging of the gas through the opening pattern OPP may not be reduced or suppressed.

While the invention has been particularly shown and described with reference to embodiments thereof, it will be understood by those of ordinary skill in the art that various changes in form and details may be made therein without departing from the spirit or scope of the invention as defined by the following claims, and their equivalents.

What is claimed is:

1. A display device comprising:
a substrate having a display area and a peripheral area adjacent to the display area;
a first wiring in the peripheral area on the substrate;
an insulating layer on the first wiring and covering at least a portion of the first wiring;
a second wiring on the insulating layer, overlapping at least a portion of the insulating layer in a plan view, and having an opening pattern exposing at least a portion of the insulating layer;
a first cladding part on the insulating layer and the second wiring to fill the opening pattern and exposing at least a portion of the second wiring; and
a second cladding part on the second wiring and covering at least a portion of the second wiring exposed from the first cladding part.

2. The display device of claim 1, wherein a thickness of the second cladding part is smaller than a thickness of the first cladding part.

3. The display device of claim 1, wherein a height from an upper surface of the insulating layer to an upper surface of the second cladding part is smaller than a height from the upper surface of the insulating layer to an upper surface of the first cladding part.

4. The display device of claim 1, wherein the second cladding part contacts the first cladding part.

5. The display device of claim 1, wherein the first cladding part is connected by the second cladding part.

6. The display device of claim 1, wherein the second cladding part is spaced apart from the opening pattern in the plan view.

7. The display device of claim 1, wherein the first cladding part contacts the insulating layer.

8. The display device of claim 1, wherein the first cladding part and the second cladding part are integrated as one body without a separate interface.

9. The display device of claim 8, wherein the first cladding part and the second cladding part include an organic material.

10. The display device of claim 1, wherein the first wiring and the second wiring contact each other to form a power voltage line, and
the power voltage line transmits a power voltage to a light emitting element in the display area.

11. A display device comprising:
a substrate having a display area and a peripheral area adjacent to the display area;
a first wiring in the peripheral area on the substrate;
an insulating layer on the first wiring and covering at least a portion of the first wiring;
a second wiring on the insulating layer, overlapping at least a portion of the insulating layer in a plan view, and having an opening pattern exposing at least a portion of the insulating layer;
a cladding film on the insulating layer and the second wiring and covering the second wiring defining the opening pattern, and at least a portion of the cladding film is in the opening pattern; and
a cladding part on the cladding film and covering at least a portion of the cladding film, and at least a portion of the cladding part is in the opening pattern.

12. The display device of claim 11, wherein the cladding part exposes at least a portion of the cladding film.

13. The display device of claim 11, wherein a thickness of the cladding film is smaller than a thickness of the cladding part.

14. The display device of claim 11, wherein a height from an upper surface of the insulating layer to an upper surface of the cladding film is smaller than a height from the upper surface of the insulating layer to an upper surface of the cladding part.

15. The display device of claim 11, wherein the cladding part contacts the cladding film.

16. The display device of claim 11, wherein the cladding part is in non-contact with the insulating layer by the cladding film.

17. The display device of claim 11, wherein the cladding film contacts the insulating layer in the opening pattern.

18. The display device of claim 11, wherein the cladding film includes an inorganic material, and
the cladding part includes an organic material.

19. The display device of claim 11, wherein the first wiring and the second wiring contact each other to form a power voltage line.

20. The display device of claim 19, wherein the power voltage line is configured to transmit a power voltage to a light emitting element in the display area.
